(19) United States
(12) Patent Application Publication
(10) Pub. No.: US 2009/0127100 A1
(43) Pub. Date: May 21, 2009

(54) FET-BASED SENSOR FOR DETECTING REDUCING GASES OR ALCOHOL, AND ASSOCIATED PRODUCTION AND OPERATIONG METHOD

(76) Inventors: Maximilian Fleischer, Hohenkirchen (DE); Gabor Kiss, Budapest (HU); Hans Meixner, Haar (DE); Uwe Lampe, Buxtehude (DE)

Correspondence Address: Patrick J. O'Shea, Esq.;O'Shea, Getz & Kosakowski, P.C., Suite 912, 1500 Main Street, Springfield, MA, 01115, US

(21) Appl. No.: 12/330,955

(22) Filed: Dec. 9, 2008

Related U.S. Application Data
(62) Division of application No. 11/587,070, filed on Dec. 18, 2006.

(30) Foreign Application Priority Data
Apr. 22, 2004 (DE) 10 2004 019 638.9

(51) Int. Cl. C23C 14/16

(52) U.S. Cl. 204/192.15

(57) ABSTRACT

An FET-based gas sensor includes at least one field-effect transistor and at least one gas-sensitive layer and a reference layer. Any changes in work function occurring when materials of the layers are exposed to a gas are used to trigger the field-effect structures. The gas-sensitive layer includes a metal oxide having an oxidation catalyst on its surface and accessible to the measured gas.

### PRIORITY INFORMATION

This patent application is a divisional of co-pending U.S. application Ser. No. 11/587,070 filed Dec. 18, 2006.

### BACKGROUND INFORMATION

This invention relates to the field of gas sensors and in particular to sensors that detect reducing gases, alcohols or hydrocarbons.

Carbon monoxide (CO) is an odorless, toxic, and explosive gas, arising during incomplete combustion of carbon or its compounds. The amounts of CO formed depend on the degree of oxygen deficit during the combustion and may reach the range of several volume percent. There is thus a great need for CO alarms that are triggered when a given maximum workplace concentration (MWC) value is exceeded. This value, for example, will be MWC=30 vpm. Typical applications occur in monitoring the air in buildings where CO can occur due to incomplete combustion, such as in underground garages, multistory parking garages, street tunnels, apartments with furnace units, or industrial environments.

Since CO is also generally formed in fires, the detection of an elevated concentration can also be used as a fire alarm. Another very important application is in automotive air quality sensors, which measure the quality of the outside air and switch the passenger compartment ventilation to recirculated air when the air quality becomes substantially impaired due to other vehicles in the area. In this case, the exhaust gases of internal combustion engines are detected in terms of CO as the monitor gas in the range of several ppm.

Many applications require economical sensors which, while they typically only detect threshold values of CO concentration, must nonetheless be very reliable. At the same time, they should have a long lifetime, minimal maintenance expense, and a low power requirement. The power requirement should be so low as to allow several months of battery operation or direct connection, without auxiliary power, to data bus lines.

Due to the need for safety and the broad applicability of CO measurement, a large number of different measurement systems are already in use today. For highest demands, expensive nondispersive infrared (NDIR) devices are used. More economical are CO sensitive electrochemical cells. However, for many applications the price of these cells is still too high and sensor systems built from them require a high maintenance expense, since the lifetime of the individual sensors is relatively short. In the lower price range are the metal oxide sensors, especially those based on SnO₂ or Ga₂O₃, whose gas reaction can be read off in terms of their change in conductance. These sensors, however, are operated at relatively high temperatures; for example, SnO₂ sensors at >300° C. or Ga₂O₃ sensors at >600° C. A high power consumption is therefore needed to reach the operating temperature. Also, these sensors are not suitable for many applications, such as fire protection, due to the need for battery operation or a direct connection, generally without auxiliary power, to the data bus.

For this reason, CO sensors are used only when required by law and therefore one must incur the necessary expenditures such as high sensor costs and furnishing the required operating power to the sensors. Outside of mandatory use, CO sensors are only employed when indispensable, e.g., for the regulating of devices and systems, and the operating power is available without additional expense, such as in motor vehicles or small furnace units. As soon as these conditions are lacking, the use of CO sensors is abandoned, even if they would be desirable for safety reasons.

Gas sensors, which use the change in the electronic work function of materials when interacting with gases as the measurement sensing technique, are suitable in theory for operating at relatively low temperatures and therefore with a low power requirement. One takes advantage of the possibility of feeding the change in work function of gas-sensitive materials to a field-effect transistor (GasFET), thereby measuring the change in work function as a change in current between the source and drain of the transistor. Typical designs are known from German Patent DE 42 39 319. The relevant technology for constructing these sensors is specified in German Patent DE 19956744.

Measurement of ethanol in the gas phase is used, for example, to deduce from the concentration of alcohol vapor in exhaled air the corresponding concentration in the blood. This is where small mobile devices are of interest, for example those which can operate with batteries or storage cells.

What is needed is a sensor for the detection, in particular, of reducing gas or gaseous alcohol, using the least possible amount of power for operation, as well as a method of fabrication and operation thereof.

### SUMMARY OF THE INVENTION

Briefly, according to one aspect of the invention, an FET-based gas sensor includes at least one field-effect transistor and at least one gas-sensitive layer and a reference layer. Any changes in work function occurring when materials of the layers are exposed to a gas are used to trigger the field-effect structure. The gas-sensitive layer comprises a metal oxide having an oxidation catalyst on its surface and accessible to the measured gas.

The present invention provides a number of advantages, including: operation with low power consumption, battery operation, or direct connection to data bus lines; small geometrical size, facilitating the creation of sensor arrays; possibility of monolithic integration of the electronics into the sensor chip; and use of sophisticated, economical methods of semiconductor fabrication.

The following two types of transistors are of special interest: suspended gate field effect transistor (SGFET); and capacitively controlled field effect transistor (CCFET). Both types are characterized by their hybrid construction, i.e., the gas-sensitive gate and the actual transistor are made separately and joined together by a suitable technology. In this way, it is possible to introduce many materials into the transistor, whose fabrication conditions are not compatible with those of silicon technology. This applies, in particular, to metal oxides, which can be laid down by thick or thin layer technology.

The invention as it applies to reducing gases, such as CO or H₂, and to alcohols or hydrocarbons, is designed to use, in an FET-based construction, a sensitive material consisting of a metal oxide, as well as an oxidation catalyst situated on the surface thereof which is accessible to the measured gas. Usually, fine dispersions of the catalyst are used.

Such systems exhibit a sudden and reversible change in their electronic work function when exposed to reducing gases in humid air and at typical operating temperatures between room temperature and 150° C. An example discussed further below is illustrated in FIG. 1. The change in the electronic work function for the relevant gas concentration range of the aforesaid applications is approximately 10-100 mV and thus is large enough to be detected with hybrid technology FET gas sensors.

The mode of functioning of these layers is based on charged adsorption of the molecules being detected on the metal oxide. The catalyst material applied serves essentially to allow these reactions to occur already in the aforesaid temperature range.

These and other objects, features and advantages of the present invention will become more apparent in light of the following detailed description of preferred embodiments thereof, as illustrated in the accompanying drawings.

### BRIEF DESCRIPTION OF THE DRAWINGS

FIG. 1 is a graph that illustrates the change in work function of a sensitive layer based on SnO₂ with Pd as the catalyst, when exposed to CO in humid air, at room temperature;

FIG. 2 is a graph that illustrates a Kelvin measurement of a Ga₂O₃ thin layer, provided with a catalyst made of finely divided platinum, the sensor temperatures lying between approximately 120° C. at 2.5 V heating voltage and approximately 220° C. at 4 V heating voltage; and

FIG. 3 is a graph that illustrates a reaction of a Pd-activated SnO₂ layer to ethanol at various temperatures.

### DETAILED DESCRIPTION OF THE INVENTION

Oxides such as SnO₂, Ga₂O₃ or CoO have proven to be especially suitable metal oxides for the detection of CO and other reducing gases. These oxides have very high stability under various environmental conditions. One can also use mixtures of different metal oxides, preferably with a fraction of one of the mentioned materials.

These materials are prepared as layers, for which one can use either cathode sputtering, silk screen methods, or CVD methods. Typical layer thicknesses lie between 1 and 3 μm. It is especially advantageous to produce a porous, e.g., an open-pore, layer of the metal oxide.

The reactivity of metal oxides at low temperatures is supported by the application of catalysts, such as oxidation-active catalysts, preferably from the group of the platinum metals or silver. The preferred metals are Pt or Pd, Rh or mixtures of these materials. The metals should preferably be present in the form of small particles, “catalyst dispersion” or “catalyst clusters,” with typical dimensions of 1-30 nm. As a result, the catalytically active metals can very often influence, i.e., increase the gas reactivity of, the metal oxides beyond the three-phase boundary (metal/metal oxide/gas).

The catalyst clusters are preferably deposited by an impregnation method, in which a salt of the precious metal is dissolved in a solvent wetting the surface of the metal oxide and this solution is applied to the surface of the prepared metal oxide. After drying, the salt is now chemically decomposed and the metallic catalyst cluster is formed. As an alternative, one can use a PVD method (e.g., cathode sputtering) to deposit a very thin (<30 nm) whole-surface layer of the catalyst. In a subsequent tempering step in the range of 600-1000° C., the whole-surface layer breaks down and once again the catalyst clusters result in the required size.

Economical CO sensors with a low power requirement are available for applications not heretofore served, for lack of the appropriate sensors.

For the first time, a sensitive layer exists with which, on the basis of or in combination with FET sensor engineering, sensors are available for reducing gases that have very low operating temperatures and operating powers.

Measurements with the Kelvin method have been performed to confirm the stability of the sensor signal, showing a CO detection at temperatures distinctly below the operating temperatures of SnO₂ and Ga₂O3 conductance sensors. The measurements are done on Pt and Pd activated thick and thin layers, by measuring the work function.

### Sensor Preparation/Preparation of Sensitive Layers

### EXAMPLE 1

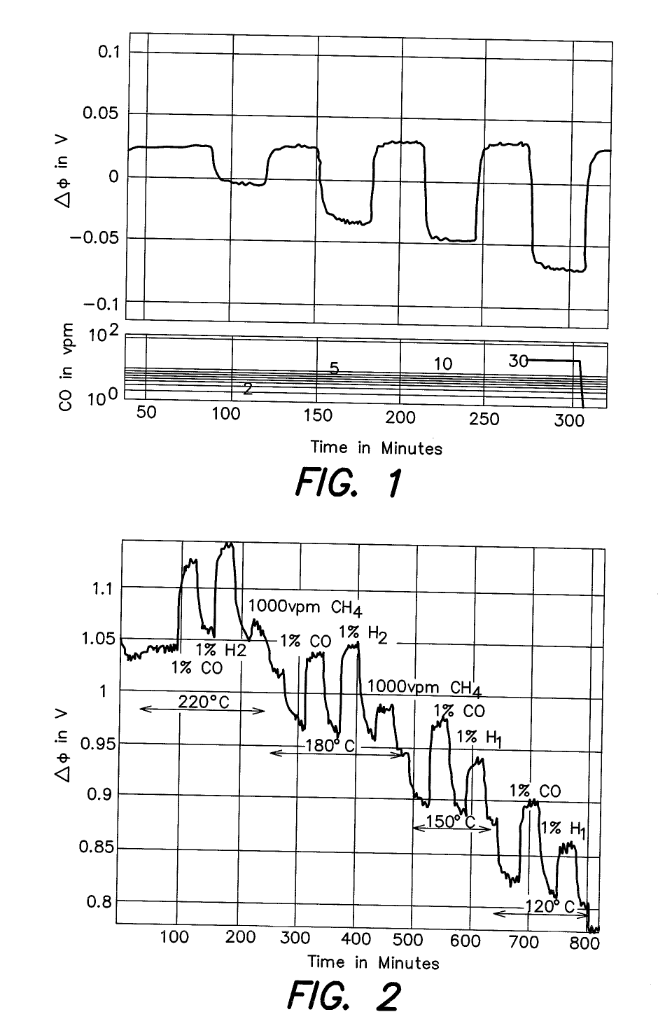

The foundation is a sputtered Ga₂O₃ thin layer with 2 μm thickness on sputtered platinum as the backside contact. Catalytic activation is done with a Pt dispersion, produced by thermal decomposition (at 600° C.) of a wet chemistry solution of a water-soluble platinum complex. The work function is measured at temperatures between approximately 220° C. and 120° C. in moist synthetic air when exposed to CO (1 vol. %), H₂ (1 vol. %), and CH₄ (1000 vpm). The result is illustrated in FIG. 2. The temperature range of the measurement lies well below the operating temperature of Ga₂O₃ conductance sensors (T>600° C.) and shows that CO detection is possible with low heating power.

### EXAMPLE 2

A Kelvin probe is produced based on an open-pore SnO₂ thick layer, baked at 600° C. The catalytic activation was done for an aqueous solution of a Pd complex, which is thermally decomposed to form Pd at temperatures between 100° C. and 250° C.

The Kelvin measurements are carried out at room temperature up to approximately 110° C. in humid synthetic air. FIG. 1 illustrates the Kelvin signal at room temperature at CO concentrations between 2 and 30 vpm CO. The measurement shows that CO can be detected with high sensitivity at low temperatures with this sensitive layer.

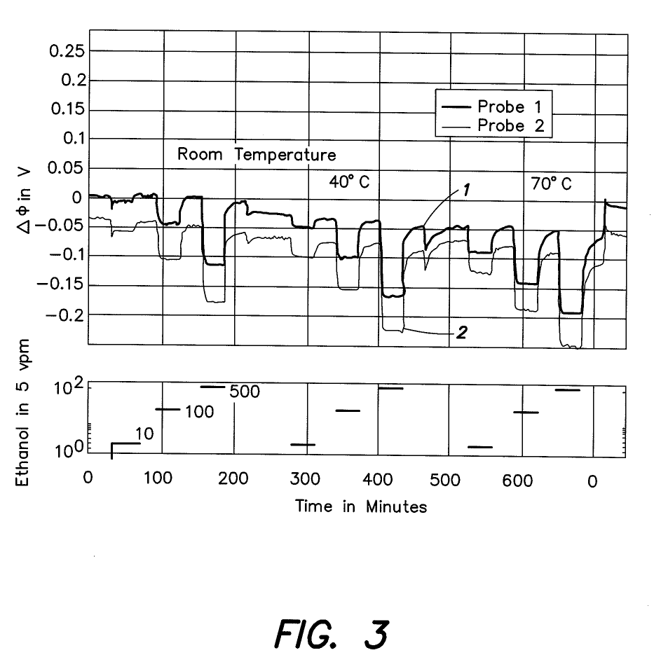

The sensitivity of the same sensitive layer to ethanol is illustrated in FIG. 3 as an example of yet another reducing gas. FIG. 3 illustrates a reaction of a Pd-activated SnO₂ layer to ethanol at various temperatures.

### Activation and Reactivation of Gas-Sensitive Layers:

The gas-sensitive layers have a tendency, when operated continuously for several weeks, to lose their high sensitivity to the target gases at room temperature. This becomes evident by a decrease in signal height, as well as an increase in response time. A remedy is possible by “reactivation” of the layer at regular intervals (e.g., every 4-5 days). The “reactivation” of the layer is done by heating the layer in humid surrounding air to temperatures between 180 and 250° C. for a period of a few minutes to no more than one hour. No other requirements, such as the presence of the target gases or the like, need be met.

Systems for detection of ethanol by means of a gas-sensitive field-effect transistor in humid air have typical values, such as operating temperature between room temperature and 100° C., as well as sudden and reversible change in electronic work function. The signal level is large enough to perform measurements. When the thickness of the tin oxide layer is uniform, a uniform air gap exists and constant signal levels are obtained.

Tin oxide and gallium oxide are especially well suited for the detection of ethanol. These oxides have very high stability under various environmental conditions. One can also use mixtures, in which at least one fraction of the aforesaid materials is contained.

A layer preparation, for example, by cathode sputtering, silk screen method, or CVD method, should produce layer thicknesses of 15 to 20 μm. Porous, especially open-pore, layers of metal oxide are advantageous. The catalyst clusters are produced by depositing a dispersion, followed by moderate tempering of the layer. As an alternative, sputtering techniques can be used for thin films, in which case tempering is again necessary. Pt or Pd can be considered as the catalyst material.

Although the present invention has been illustrated and described with respect to several preferred embodiments thereof, various changes, omissions and additions to the form and detail thereof, may be made therein, without departing from the spirit and scope of the invention.

What is claimed is:

1. A method for fabrication of a gas sensor, comprising the steps of:
producing a sputtered Ga₂O₃ thin layer with thickness of 2 μm on sputtered platinum as a backside contact; and
preparing catalytically active regions by applying a Pt dispersion to the sputtered Ga₂O₃ thin layer, where the step of applying a Pt dispersion is carried out by thermal decomposition of a solution of a soluble platinum complex.

2. The method of claim 1, further comprising the steps of:
preparing a sensitive layer on the basis of a porous SnO2 thick layer, which is baked at 600° C.; and
where the step of preparing the catalytically active regions is carried out by application of a solution of a Pd complex, which is broken down thermally into Pd at temperatures between 100° C. and 250° C.

3. The method of claim 1, where the operating temperature of the sensitive layer lies between room temperature and 150° C.

4. The method of claim 1, where the sensor structure is heated at predetermined intervals of 1 day to 1 month of sensor operating time to an elevated temperature between 180-250° C.

5. A method for fabricating a gas sensor, comprising the steps of:
providing a layer of a metal oxide with a predetermined thickness; and
applying a catalyst in the form of particles to a first surface of the metal oxide layer.

6. The method of claim 5, further comprising the step of providing a layer of sputtered platinum to a second surface of the metal oxide layer.

7. The method of claim 5, where the step of providing the metal oxide layer comprises the step of fabricating the metal oxide layer from one of the methods comprising cathode sputtering, silk screening and CVD.

8. The method of claim 5, where the step of applying the catalyst comprises the steps of depositing by impregnation a salt of a predetermined metal that is dissolved in a solvent that wets the first surface of the metal oxide layer and depositing the resulting solution to the first surface of the metal oxide layer.
